(19) United States
(12) Patent Application Publication
(10) Pub. No.: US 2012/0217986 A1
(43) Pub. Date: Aug. 30, 2012

(54) MODULE ASSEMBLY HOLDING WORKBOARD

(75) Inventors: Alan F. Benner, Poughkeepsie, NY (US); Kenneth Y. Chan, Fishkill, NY (US); Yvan Cossette, Bromont (CA); Eric E. Dube, Bromont (CA); Benjamin V. Fasano, New Windsor, NY (US); Michael J. Fisher, Poughkeepsie, NY (US); Gilles Labbe, Waterloo (CA); Pierre Laroche, Sherbrooke (CA); Stephen P. Mroz, Rochester, MN (US); Steven P. Ostrander, Poughkeepsie, NY (US); Justin C. Rogers, Rochester, MN (US); Etienne St-Pierre, Farnham (CA)

(73) Assignee: INTERNATIONAL BUSINESS MACHINES CORPORATION, Armonk, NY (US)

(21) Appl. No.: 13/033,711

(22) Filed: Feb. 24, 2011

(51) Int. Cl. G01R 31/20; H05K 7/00

(52) U.S. Cl. 324/750.25; 361/679.01

(57) ABSTRACT

A module assembly holding workboard is provided and includes a base having a central portion to support a computing module, a first wing at a first side of the central portion to support a first adapter and a second wing at a second side of the central portion to support a second adapter, the first and second adapters being coupled to the computing module via first and second conductive elements and a plurality of routing channel elements fixedly disposed at the first and second wings to retain the first and second conductive elements.

This invention was made with Government support under Contract No. HR0011-07-9-0002 awarded by (DARPA) the Defense Advanced Research Projects Agency. The Government has certain rights to this invention.

### BACKGROUND

In computing device and semi-conductor manufacturing processes, it is often necessary to test integrated circuit modules at a manufacturing environment before the integrated circuit modules can be shipped to customers. The integrated circuit modules typically have optical fibers connected thereto that can be up to four feet long and usually not well protected. As a result, handling and the testing of the integrated circuit modules in the manufacturing environment must be done with extreme care and the requirement for such extreme care represents an added cost to the total costs of manufacturing.

### SUMMARY

In accordance with an aspect of the invention, a module assembly holding workboard is provided and includes a base having a central portion to support a computing module, a first wing at a first side of the central portion to support a first adapter and a second wing at a second side of the central portion to support a second adapter, the first and second adapters being coupled to the computing module via first and second conductive elements and a plurality of routing channel elements fixedly disposed at the first and second wings to retain the first and second conductive elements.

In accordance with another aspect of the invention, a module assembly holding workboard is provided and includes a base having a central portion to support an integrated circuit (IC) module, a first wing at a first side of the central portion to support a first adapter and a second wing at a second side of the central portion to support a second adapter, the first and second adapters having different formats and being coupled to the computing module via first and second optical fibers and a plurality of routing channel elements fixedly disposed at the first and second wings to retain the first and second conductive elements proximate to respective surfaces of the first and second wings with substantially smooth curvatures.

In accordance with an aspect of the invention, a method of testing an operation of an integrated circuit (IC) module and connections between first and second optical fibers with the IC module is provided and includes coupling first and second adapters to the IC module via the first and second optical fibers, respectively, forming a base to support the IC module and the first and second adapters, retaining the first and second optical fibers to the base, placing the base in a machine to test the operation of the IC module and the connections and removing the base from the machine and shipping the IC module with the base if the test is successful.

### BRIEF DESCRIPTIONS OF THE SEVERAL VIEWS OF THE DRAWINGS

The subject matter regarded as the invention is particularly pointed out and distinctly claimed in the claims at the conclusion of the specification. The foregoing and other aspects, features, and advantages of the invention are apparent from the following detailed description taken in conjunction with the accompanying drawings in which:

FIG. 1 is a perspective view of a workboard base;

FIG. 2 is a perspective view of an underside of the workboard base of FIG. 1;

FIG. 3 is an enlarged perspective view of the workboard base of FIG. 1; and

FIG. 4 is a flow diagram illustrating uses of the workboard base at various points in time.

### DETAILED DESCRIPTION

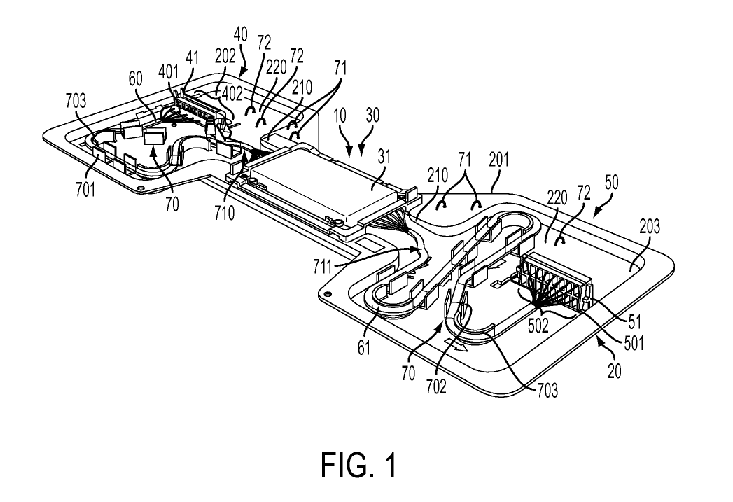

With reference to FIGS. 1-3 and, in accordance with aspects of the present invention, a carrier or base is provided as a module assembly holding workboard 10 for an electrical assembly. The module assembly holding workboard 10 provides mechanical stability for assembly as well as a retention feature design that securely holds a module assembly during at least assembly processes and testing. The module assembly holding workboard 10 has an open top and bottom design to allow for component placement, mechanical assembly and testing with full surface pad access. There are also optical fiber routing and retention features to retain and protect optical fibers, optical fiber terminating adapter blocks to provide for a unitized assembly for placement onto a next level of packaging, such as a card or a node, and sliding retention features to hold the module assembly holding workboard 10 in place during shipment with quick release capability. The module assembly holding workboard 10 is reusable/recyclable and is protectable by a specially designed shipping box.

The module assembly holding workboard 10 includes a base 20 and a plurality of routing channel elements 70. The base 20 has a central portion 30 to support a computing module, such as an integrated circuit (IC) module 31, a first wing 40 at a first side of the central portion 30 to support a first adapter 41 and a second wing 50 at a second side of the central portion 30 to support a second adapter 51. The first and second adapters 41 and 51 are coupled to the IC module 31 via first and second conductive elements, such as first and second sets of optical fiber ribbons 60 and 61 that may have different respective lengths. Each of the plurality of routing channel elements 70 is fixedly disposed at the first and second wings 40 and 50 to retain the first and second sets of optical fiber ribbons 60 and 61.

The first and second sets of optical fiber ribbons 60 and 61 may include one or more individual optical fiber ribbons. In one embodiment, the first set of optical fiber ribbons 60 includes a stack of between 2 and 24 ribbons, with each ribbon being about 3 mm wide and 0.33 mm high. The stack of, for example, 24 ribbons would therefore be 24*0.33=8 mm high. Each ribbon in this stack is rotated by 90 degrees as it comes out of the IC module 31, so that the stack can be routed through routing channels to be described below. Another similar type of stack may be provided in the second set of optical fiber ribbons 61.

In accordance with embodiments, the base 20 is formed of a rigid, non-conductive material that provides for structural support during assembly, testing and shipping phases. The base 20 may be substantially symmetric about a central axis. This symmetry facilitates assembly, handling and insertion/retraction into/from testing machinery of the module assembly holding workboard 10. In particular, the base 20 may have a bow-tie shape whereby the first and second wings 40 and 50 have substantially similar shapes and extend laterally from opposite sides of the central portion 30. In this case, the first and second wings 40 and 50 are generally wider than the central portion 30. The bow-tie shape is associated with size and shape requirements of certain IC module 31 testing machinery but, it is to be understood that the base 20 may have other regular and irregular shapes as well.

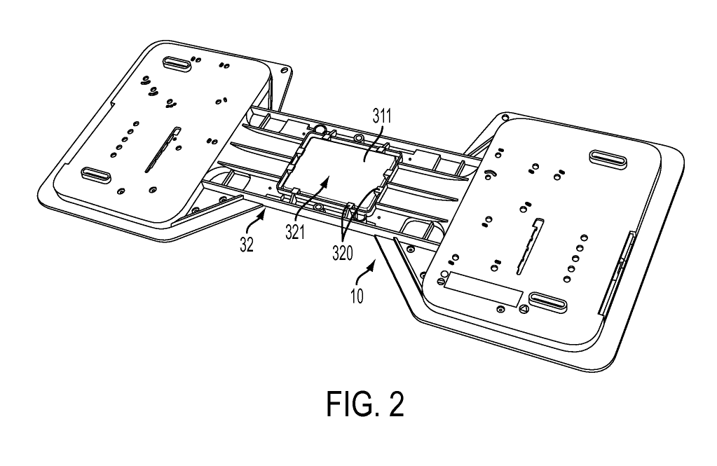

As shown in FIG. 2, the IC module 31 is accessible via an underside 32 of the central portion 30. That is, the underside 32 of the central portion 30 may be provided as a plurality of sidewalls 320 that are formed to define an aperture 321. This aperture 321 provides for access to, for example, an input/output (I/O) contact surface 311 of the IC module 31. In this way, the IC module 31 may be mounted on test equipment that allows for powering and testing of the IC module 31 without having to remove the IC module 31 from the module assembly holding workboard 10.

The base 20 includes a primary surface 201 and first and second recessed surface pads 202 and 203. The primary surface 201 forms the outer appearance of the base 20 (i.e., the bowtie shape) and supports the IC module 31. The recessed surface pads 202 and 203 are provided at the first and second wings 40 and 50, respectively, such that a plane of each of the recessed surfaces 202 and 203 is recessed from a plane of the primary surface 201. Each of the recessed surface pads 202 and 203 generally mimics a shape of the corresponding one of the wings 40 and 50 and includes a curved neck section 210 that gets wider with increasing distance from the central portion 30 and a main section 220 that communicates with the curved neck section 210.

The first and second adapters 41 and 51 are each supported at the recessed surface pads 202 and 203 of the first and second wings 40 and 50, respectively. The first and second adapters 41 and 51 may have similar and/or varying formats and include respective bases 401 and 501 on which respective arrays of connection leads 402 and 502 are disposed. The respective bases 401 and 501 are affixed to the recessed surface pads 202 and 203. In one exemplary embodiment, the first adapter 41 may have a 1×6 adapter format with 1 row of 6 connection leads 402 while the second adapter 51 may have a 2×8 adapter format with 2 rows of 8 connection leads 502. The number of connection leads is predefined in accordance with numbers of individual optical fibers in each set of optical fiber ribbons 60 and 61, which are in turn predefined in accordance with a number of associated connection leads on the IC module 31.

The module assembly holding workboard 10 further includes sliding retention features, such as pluralities of secondary routing channel elements 71 and tertiary routing channel elements 72. The plurality of secondary routing channel elements 71 may be fixedly disposed at the primary surface 201 and the plurality of tertiary routing channel elements 72 may be fixedly disposed at the recessed surfaces 202 and 203. In each case, the sliding retention features facilitate handling, testing and shipping of the module assembly holding workboard 10 at each of various points in assembly, testing and commercial phases.

The plurality of routing channel elements 70 retains the first and second sets of optical fiber ribbons 60 and 61 between a plane of the primary surface 201 and a plane of the recessed surfaces 202 and 203. To this end, the plurality of routing channel elements 70 includes a first portion of routing channel elements 701 and a second portion of routing channel elements 702. The first portion of routing channel elements 701 retains the first set of optical fiber ribbons 60 between the plane of the primary surface 201 and the plane of the recessed surface 202 of the first wing 40. The second portion of routing channel elements 702 retains the second set of optical fiber ribbons 61 between the plane of the primary surface 201 and the plane of the recessed surface 203 of the second wing 50. The plurality of routing channel elements 70 may further include wall elements 703 to support and guide the sets of optical fiber ribbons 60 and 61 at the curvatures thereof.

In particular, the first portion of routing channel elements 701 is arranged to define a first routing channel 710 at the first wing 40 along which the first set of optical fiber ribbons 60 is extendable with a first number of smooth curvatures. Similarly, the second portion of routing channel elements 702 is arranged to define a second routing channel 711 at the second wing 50 along which the second set of optical fiber ribbons 61 is extendable with a second number of smooth curvatures. Here, the smooth curvatures refer to curves along the sets of optical fiber ribbons 60 and 61 that have sufficiently large curvature radii such that the sets of optical fiber ribbons 60 and 61 do not bend sharply or fold. Such sharp bends and/or folds can negatively affect the ability of the sets of optical fiber ribbons 60 and 61 to operate properly and are to be avoided. The first and second numbers of the smooth curvatures are predefined in accordance with respective dimensions of the first and second sets of optical fiber ribbons 60 and 61. That is, short and long sets of ribbons will tend to require lesser and greater number of curvatures, respectively. Also, relatively wide sets of ribbons will tend to require increased curvature radii to avoid sharp bens and/or folds whereas relatively narrow sets of ribbons can accommodate smaller curvature radii without sharp bends and/or folds.

This can be seen in FIG. 1 in which the first set of optical fiber ribbons 60 is relatively short length-wise and extends along first routing channel 710 with three relatively gentle curvatures. By contrast, the second set of optical fiber ribbons 61 is relatively long length-wise and extends along second routing channel 711 with four curvatures of which the first is relatively gentle but the second, third and fourth are more extreme hairpin type curvatures.

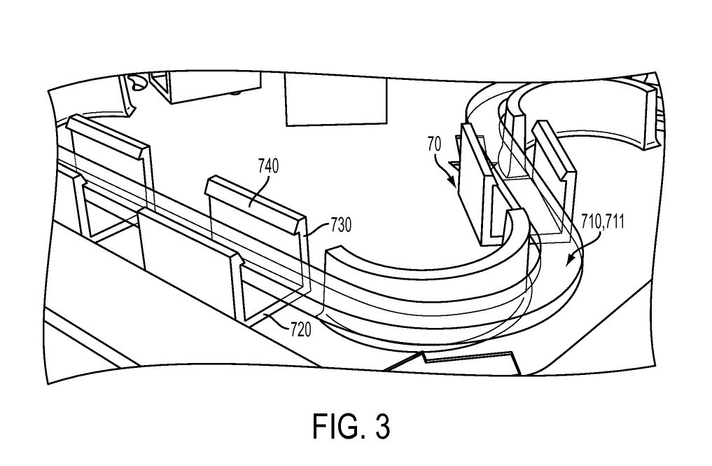

As shown in FIG. 3, each of the plurality of routing channel elements 70 has a base 720 and a plurality of legs 730. The base 720 is affixed to the corresponding surface portion of the base 20 by, for example, an integral connection or an adhesive. Each of the plurality of legs 730 extends from the base 20 in substantially similar directions and includes a hook portion 740 at a respective distal end thereof. The plurality of legs 730 are arranged such that pairs of opposite hook portions 740 are defined with separation distance that exceeds the width of the corresponding one of the sets of optical fiber ribbons 60 and 61 that is to be inserted therein. During assembly, the sets of optical fiber ribbons 60 and 61 are twisted by about 90 degrees or less and inserted into the first and second routing channels 710 and 711 between the pairs of opposite hook portions 740. Once insertion is complete, the sets of optical fiber ribbons 60 and 61 are returned to their upright orientation.

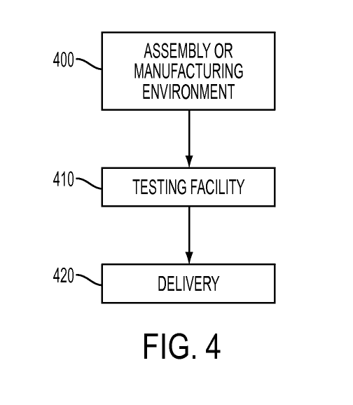

With reference to FIG. 4, a method of testing an operation of the integrated circuit (IC) module 31 and connections between the first and second sets of optical fibers 60 and 61 with the IC module 31 is provided. The method includes coupling the first and second adapters 41 and 51 to the IC module 31 via the first and second sets of optical fibers 60 and 61, respectively, forming the base 20 to support the IC module 31 and the first and second adapters 41 and 51 and retaining the first and second sets of optical fibers 60 and 61 to the base 20 with smooth curvatures. The forming operation may include forming the base 20 with a substantially symmetric bowtie shape from rigid, non-conductive material and may be accomplished by molding, extrusion, machining and/or other similar processes. The coupling operations, the forming operations and the retaining operations cooperatively form the module assembly holding workboard 10 and may be accomplished at an assembly environment 400.

Once the coupling operations, the forming operations and the retaining operations are accomplished at the assembly environment 400, the module assembly holding workboard 10 is moved to a testing sector or facility 410. Here, the method further includes operations of placing the module assembly holding workboard 10 in a machine to test the operation of the IC module 31 and the connections and removing the module assembly holding workboard 10 from the machine. Finally, if the test is deemed a success, the IC module 31 is shipped to a customer 420 with the module assembly holding workboard 10.

While the disclosure has been described with reference to exemplary embodiments, it will be understood by those skilled in the art that various changes may be made and equivalents may be substituted for elements thereof without departing from the scope of the disclosure. In addition, many modifications may be made to adapt a particular situation or material to the teachings of the disclosure without departing from the essential scope thereof. Therefore, it is intended that the disclosure not be limited to the particular exemplary embodiment disclosed as the best mode contemplated for carrying out this disclosure, but that the disclosure will include all embodiments falling within the scope of the appended claims.

What is claimed is:

1. A module assembly holding workboard, comprising:
a base having a central portion to support a computing module, a first wing at a first side of the central portion to support a first adapter and a second wing at a second side of the central portion to support a second adapter,
the first and second adapters being coupled to the computing module via first and second conductive elements; and
a plurality of routing channel elements fixedly disposed at the first and second wings to retain the first and second conductive elements.

2. The module assembly holding workboard according to claim 1, wherein the base is formed of a rigid, non-conductive material.

3. The module assembly holding workboard according to claim 1, wherein the base is substantially symmetric about a central axis.

4. The module assembly holding workboard according to claim 1, wherein the base has a bow-tie shape.

5. The module assembly holding workboard according to claim 1, wherein computing module is accessible via an underside of the central portion.

6. The module assembly holding workboard according to claim 1, wherein the base comprises a primary surface on which the computing module is supported and recessed surfaces at the first and second wings.

7. The module assembly holding workboard according to claim 6, wherein a plane of the recessed surfaces is recessed from a plane of the primary surface.

8. The module assembly holding workboard according to claim 6, wherein the first and second adapters are each supported at the recessed surfaces of the first and second wings, respectively.

9. The module assembly holding workboard according to claim 6, further comprising a plurality of secondary routing channel elements fixedly disposed at the primary surface.

10. The module assembly holding workboard according to claim 6, further comprising a plurality of tertiary routing channel elements fixedly disposed at the recessed surfaces.

11. The module assembly holding workboard according to claim 6, wherein the plurality of routing channel elements retain the first and second conductive elements between a plane of the primary surface and a plane of the recessed surfaces.

12. The module assembly holding workboard according to claim 1, wherein the plurality of routing channel elements comprise:
a first portion of routing channel elements to retain the first conductive element to the first wing; and
a second portion of routing channel elements to retain the second conductive element to the second wing.

13. The module assembly holding workboard according to claim 12, wherein the first and second conductive elements have different lengths.

14. The module assembly holding workboard according to claim 12, wherein:
the first portion of routing channel elements defines a first routing channel at the first wing along which the first conductive element is extendable with a first number of smooth curvatures, and
the second portion of routing channel elements defines a second routing channel at the second wing along which the second conductive element is extendable with a second number of smooth curvatures.

15. The module assembly holding workboard according to claim 14, wherein the first and second numbers of the smooth curvatures are predefined in accordance with respective dimensions of the first and second conductive elements.

16. The module assembly holding workboard according to claim 1, wherein each of the plurality of routing channel elements comprises:
a base; and
a plurality of legs extending from the base, each leg including a hook portion at a distal end thereof.

17. The module assembly holding workboard according to claim 16, wherein the plurality of legs are arranged such that pairs of opposite hook portions are defined.

18. A module assembly holding workboard, comprising:
a base having a central portion to support an integrated circuit (IC) module, a first wing at a first side of the central portion to support a first adapter and a second wing at a second side of the central portion to support a second adapter,
the first and second adapters having different formats and being coupled to the computing module via first and second optical fibers; and
a plurality of routing channel elements fixedly disposed at the first and second wings to retain the first and second conductive elements proximate to respective surfaces of the first and second wings with substantially smooth curvatures.

19. The module assembly holding workboard according to claim 18, wherein the base is formed of rigid, non-conductive material.

20. The module assembly holding workboard according to claim 18, wherein the base is substantially symmetric about a central axis.

21. The module assembly holding workboard according to claim 18, wherein the base has a bow-tie shape.

22. A method of testing an operation of an integrated circuit (IC) module and connections between first and second optical fibers with the IC module, the method comprising:
coupling first and second adapters to the IC module via the first and second optical fibers, respectively;
forming a base to support the IC module and the first and second adapters;
retaining the first and second optical fibers to the base;
placing the base in a machine to test the operation of the IC module and the connections; and
removing the base from the machine and shipping the IC module with the base if the test is successful.

23. The method according to claim 22, wherein the forming comprises forming the base with a substantially symmetric bowtie shape from rigid, non-conductive material.

24. The method according to claim 22, wherein the forming of the base comprises molding.

25. The method according to claim 22, wherein the retaining comprises retaining the first and second optical fibers with smooth curvatures.
